(19) United States
(12) Patent Application Publication
(10) Pub. No.: US 2023/0402329 A1
(43) Pub. Date: Dec. 14, 2023

(54) TESTKEY STRUCTURE AND MONITORING METHOD WITH TESTKEY STRUCTURE

(71) Applicant: United Semiconductor (Xiamen) Co., Ltd., Xiamen (CN)

(72) Inventors: Hang Liu, Shamen City (CN); LINSHAN YUAN, Shamen City (CN); Guang Yang, Xiamen (CN); Yi Lu Dai, Shamen City (CN); JINJIAN OUYANG, Xiamen (CN); Chin-Chun Huang, Hsinchu County (TW); WEN YI TAN, Xiamen (CN)

(73) Assignee: United Semiconductor (Xiamen) Co., Ltd., Xiamen (CN)

(21) Appl. No.: 17/873,189

(22) Filed: Jul. 26, 2022

(30) Foreign Application Priority Data
Jun. 8, 2022 (CN) 202210644138.X

(51) Int. Cl. H01L 21/66; G01R 31/28

(52) U.S. Cl. CPC H01L 22/14; H01L 22/34; G01R 31/2884

(57) ABSTRACT

The present disclosure provides a testkey structure and a monitoring method with a testkey structure, and the testkey structure includes a first diffusion region and a second diffusion region, a first gate and a second gate, a first epitaxial layer and a second epitaxial layer, and an input pad and an output pad. The first diffusion region and the second diffusion region are disposed in a substrate. The first gate and the second gate are disposed on a substrate, across the first diffusion region and the second diffusion region respectively. The first epitaxial layer and the second epitaxial layer are respectively disposed on the second diffusion region and the first diffusion region, separately disposed between the first gate and the second gate. The input pad and the output pad are electrically connected to the first epitaxial layer and the second epitaxial layer respectively.

### BACKGROUND OF THE INVENTION

### 1. Field of the Invention

The present disclosure relates generally to a testkey structure and a monitoring method with a testkey structure, and more particularly to a testkey structure for a semiconductor device and a monitoring method for monitoring spacing within the semiconductor device by using a testkey structure.

### 2. Description of the Prior Art

With the development of integration circuit, the low electricity consumption and high integration of metal-oxide-semiconductor (MOS) transistors allows them to be widely applied in the semiconductor process. Usually, a MOS transistor includes a gate and two doping regions at two sides thereof, serving as a source and a drain respectively. In some situation, an epitaxial layer for example including silicon germanium (SiGe) may be optionally formed within the doping regions through a selective epitaxial growth (SEG) technique, to further improve the carrier mobility of the MOS transistor.

According to the advanced semiconductor fabricating technology, the structural health between two adjacent MOS transistors, especially the required distance between two silicon germanium epitaxial layers, is the most critical step during the fabrication. If the location of shallow trench isolation (STI) between the two MOS transistors becomes too high, the coverage of the two doping regions become too wide, or the structure of the epitaxial layers becomes too large, the structural health of the two MOS transistors will be seriously affected thereby. In general, in order to ensure the stability of product quality after production, it is necessary to repeatedly testing the products, for example using software for measuring the surface distance, such as a Pro-v measuring tool, to measure the distance between adjacent epitaxial layers during the corresponding fabricating step. However, the Pro-v measuring tool is inadequate to find the structural defect of all products in an immediate and comprehensive manner, so that, the semiconductor products are easily to face current leakage or even low yield issues in mass production. Thus, the currently technique still requires further improvements to meet the industrial requirements, so as to effectively monitor the structural health of the structures adjacent thereto within the semiconductor device.

### SUMMARY OF THE INVENTION

An object of the present disclosure is to provide a testkey structure and a monitoring method with a testkey structure, in which the testkey structure is disposed on each wafer for fast and precisely monitoring the spacing between the specific semiconductor structures in a non-destructive manner. In this way, the testkey structure and the monitoring method of the present disclosure are beneficial on improving the fabricating tolerance of the semiconductor process, thereby effectively avoiding the current leakage caused by structural defects, and further increasing the yield of products after mass production.

To achieve the aforementioned objects, the present disclosure provides a testkey structure including a first diffusion region and a second diffusion region, a first gate and a second gate, a first epitaxial layer and a second epitaxial layer, and an input pad and an output pad. The first diffusion region and the second diffusion region are disposed in a substrate. The first gate and a second gate are disposed on the substrate, across the first diffusion region and the second diffusion region respectively. The first epitaxial layer and the second epitaxial layer are disposed on the first diffusion region and the second diffusion region respectively, wherein the first epitaxial layer and the second epitaxial layer are separately disposed between the first gate and the second gate. The input pad and the output pad are electrically connected to the first epitaxial layer and the second epitaxial layer respectively.

To achieve the aforementioned objects, the present disclosure provides a monitoring method with a testkey structure including the following steps. Firstly, a testkey structure is provided in a semiconductor device, the testkey structure includes a first diffusion region and a second diffusion region, a first gate and a second gate, a first epitaxial layer and a second epitaxial layer, and an input pad and an output pad. The first diffusion region and the second diffusion region are disposed in a substrate. The first gate and a second gate are disposed on the substrate, across the first diffusion region and the second diffusion region respectively. The first epitaxial layer and the second epitaxial layer are disposed on the first diffusion region and the second diffusion region respectively, wherein the first epitaxial layer and the second epitaxial layer are separately disposed between the first gate and the second gate. The input pad and the output pad are electrically connected to the first epitaxial layer and the second epitaxial layer respectively. Next, a first signal is transmitted to the input pad, and a leakage between the first epitaxial layer and the second epitaxial layer is identified through receiving a first corresponding signal from the output pad.

According to the present disclosure, a semiconductor structure is disposed in a component region of a semiconductor device, and at least one testkey structure which is corresponding to the semiconductor structure is simultaneously disposed in a testkey region of the semiconductor device, wherein a first epitaxial layer and a second epitaxial layer are disposed in the component region, with a spacing being defined therebetween, and a corresponding first epitaxial layer and a corresponding second epitaxial layer are disposed in the testkey region with the same spacing being defined therebetween. Through these arrangements, the spacing between the first epitaxial layer and the second epitaxial layer in the component region may be correspondingly simulated and monitored by using the testkey structure in the testkey region, so that, the present disclosure is allowable to effectively monitor the fabrication tolerance of the semiconductor process, thereby effectively avoiding the possible leakage caused by structural defects between adjacent structures, and further increasing the product yield after mass production.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 2 illustrate schematic diagrams of a testkey structure according to one embodiment of the present disclosure, in which:

FIG. 1 is a schematic top view of a testkey structure; and

FIG. 2 is a schematic cross-sectional view of a testkey structure.

FIG. 3 illustrates a schematic flowchart of a monitoring method with a testkey according to one embodiment of the present disclosure.

FIG. 4 illustrates a schematic top view of a testkey structure according to another embodiment of the present disclosure.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

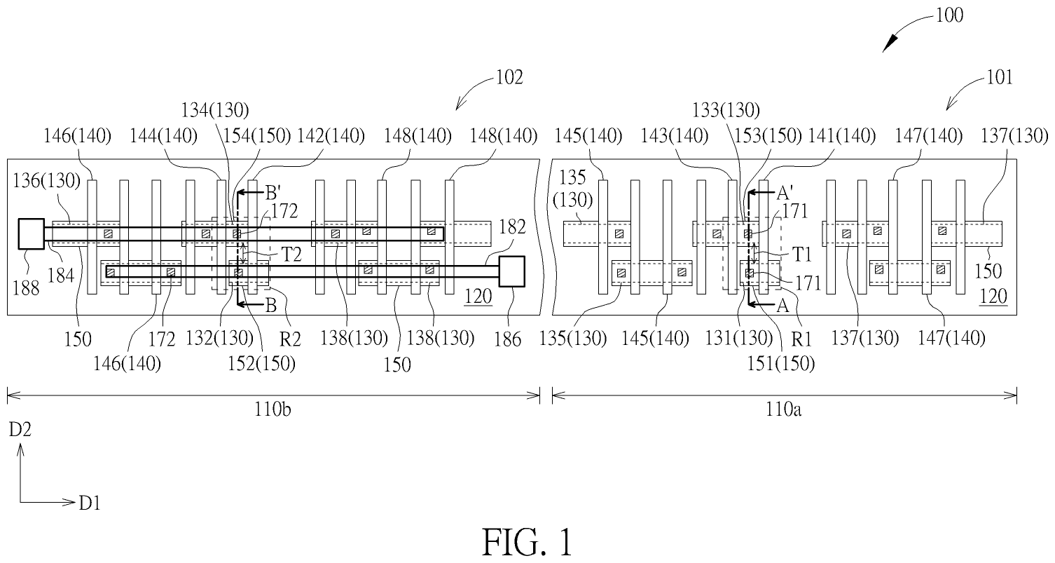

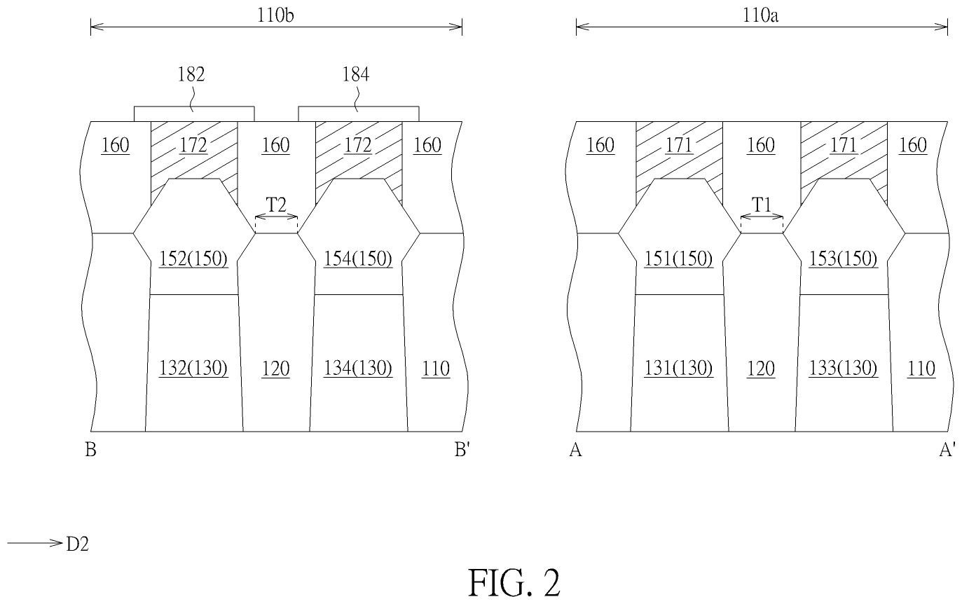

Please refer to FIG. 1 to FIG. 2, which respectively illustrate a top view and a cross-sectional view of a testkey structure 102 according to one embodiment of the present disclosure. Firstly, as shown in FIG. 1 and FIG. 2, a semiconductor device 100 is provided, and which includes a substrate 110 for example a silicon substrate, an epitaxial silicon substrate, a silicon containing substrate or a silicon-on-insulator (SOI) substrate. The substrate 110 for example includes a component region 110a and a testkey region 110b, and the component region 110a may include any type of semiconductor elements based on practical requirements, such as a N-type metal-oxide semiconductor (NMOS) transistor, a P-type metal-oxide semiconductor (PMOS) transistor, a static random-access memory (SRAM), or a capacitor, wherein the testkey region 110b may be disposed directly adjacent to the component region 110a, or disposed within a periphery region or within a scribe line of each die region, but is not limited thereto.

Each of the component region 110a and the testkey region 110b may further include at least one isolating region such as a shallow trench isolation 120, and at least one diffusion region 130. In one embodiment, the formation of the at least one isolating region is accomplished by performing a photolithography process of the substrate 110 for example, which includes but not limited to the following steps. Firstly, a mask layer (not shown in the drawings) is used to form at least one trench (not shown in the drawings) in the substrate 110, an isolating material is then filled into the trench, and the mask layer is removed after a planarization process is performed on the isolating material. Accordingly, the shallow trench isolation 120 is formed in the substrate 110. In another embodiment, the shallow trench isolation 120 may also be replaced by other isolating elements, for example, a field oxide layer (FOX, not shown in the drawings) formed by directly and locally oxidizing the surface of the substrate 110, but not limited thereto.

On the other hand, the formation of the at least one diffusion region 130 may be accomplished by performing a general semiconductor fabricating process. For example, after forming the shallow trench isolation 120, another mask layer (not shown in the drawings) is used to carry out an ion implantation process in the substrate 110, outside the shallow trench isolation 120, and then, the mask layer is completely removed. Accordingly, the at least one diffusion region 130 may be surrounded by the shallow trench isolation 120. Also, as the continuously increased integrity of the semiconductor elements, a plurality of fin-shaped structures (not shown in the drawings) may be previously formed on the substrate 110, and the at least one diffusion region 130 is then formed in the fin-shaped structures which are protruded from the top surface of the substrate 110, wherein the formation of the fin-shaped structures includes but not limited to the following steps. Firstly, a patterned mask (not shown in the drawings) is formed on the substrate 110, and an etching process is performed through the patterned mask to transfer the pattern of the patterned mask into the substrate 110 underneath, to form the fin-shaped structures. Otherwise, a patterned hard mask layer (not shown in the drawings) is formed on the substrate 110, and a selective epitaxial growth (SEG) process is performed through the patterned hard mask layer, to form a semiconductor layer (not shown in the drawings, for example including a material like silicon germanium) through the substrate 110 exposed from the patterned hard mask layer, thereby serving as corresponding fin-shaped structures. Otherwise, the fin-shaped structures may also be formed through a sidewall aligned double patterning (SADP) process. In the present embodiment, the at least one diffusion region 130 is exemplified by being disposed in the fin-shaped structures.

precisely speaking, the at least one diffusion region 130 disposed within the testkey region 110b further includes a first diffusion region 132, a second diffusion region 134, a plurality of third diffusion regions 136, and a plurality of fourth diffusion regions 138. In the present embodiment, the first diffusion region 132, the second diffusion region 134, the third diffusion regions 136 and the fourth diffusion regions 138 are separately and parallel extended in a first direction D1 (for example the x-direction), wherein the second diffusion region 134 and the first diffusion region 132 may be sequentially arranged along a second direction D2 (for example the y-direction) which is perpendicular to the first direction D1, as shown in FIG. 1. Furthermore, along the first direction D1, the third diffusion regions 136 are for example all disposed at a first side (for example the left side as shown in FIG. 1) of the first diffusion region 132 and the second diffusion region 134, to align with the first diffusion region 132 and the second diffusion region 134, and the fourth diffusion regions 138 are for example all disposed at a second side (for example the right side as shown in FIG. 1) of the first diffusion region 132 and the second diffusion region 134, to also align with the first diffusion region 132 and the second diffusion region 134, but not limited thereto. The second side is opposite to the first side. People skilled in the art should fully understand that in the present embodiment, the practical disposing features and the practical disposing number of the diffusion regions 130 (including the first diffusion region 132, the second diffusion region 134, the third diffusion regions 136, and the fourth diffusion regions 138) are not limited to be what is shown in FIG. 1, and which may include other variation, or further include any suitable type or shape.

As further in view in FIG. 1, the testkey region 110b further includes a plurality of gates 140 extended in the second direction D2, the gates 140 are separately disposed on the substrate 110, wherein a first gate 142 and a second gate 144 are respectively disposed across the first diffusion region 132 and the second diffusion region 134, with the first diffusion region 132, the second diffusion region 134, the first gate 142, and the second gate 144 being together arranged into a rectangular shape R2. Also, a plurality of third gates 146, and a plurality of fourth gates 148 are respectively disposed at the first side and the second side of the first gate 142 and the second gate 144, so that, the third gates 146 may cross the third diffusion regions 136 or the second diffusion region 134 respectively, and the fourth gates 148 may cross the fourth diffusion regions 138 respectively. It is noted that, the testkey region 110b further includes a plurality of epitaxial layers 150 disposed on each of the diffusion regions 130, and the formation of the epitaxial layers 150 may also be accomplished through the general semiconductor fabricating process, which includes but not limited to the following steps. Firstly, each of the diffusion regions 130 exposed from two sides of each of the gates 140 are partially removed, and the epitaxial layers 150 are formed to protrude from the surfaces of the substrate 110 for example via a selective epitaxial growth process, wherein the epitaxial layers 150 for example includes a material like silicon germanium. In the present embodiment, each of the epitaxial layers 150 preferably includes a cross-section with various shapes, such as hexagon (also known as sigma 1) or octagon as shown in FIG. 2, or other shapes.

Precisely speaking, the epitaxial layers 150 further includes a first epitaxial layer 152 disposed on the first diffusion region 132, and a second epitaxial layer 154 disposed on the second diffusion region 134, wherein the first epitaxial layer 152 and the second epitaxial layer 154 are disposed between the first gate 142 and the second gate 144, also within the rectangular shape R2, as shown in FIG. 1. In one embodiment, the first epitaxial layers 152 and the second epitaxial layer 154 may include any suitable material according to the type of the metal-oxide semiconductor (MOS) transistor, for example including SiGe, SiGeB, SiGeSn, SiC, SiCP, or SiP. Preferably, the first epitaxial layer 152 and the second epitaxial layer 154 may both include SiGe, so that, the first diffusion region 132 and the second diffusion region 134, the first gate 142 and the second gate 144, and the first epitaxial layer 152 and the second epitaxial layer 154 may together form at least two P-type metal-oxide semiconductor (PMOS) transistors, but not limited thereto.

In another embodiment, the first epitaxial layer 152 and the second epitaxial layer 154 may further include a multilayer structure. For example, another epitaxial structure may be additionally formed on the SiGe epitaxial layer, with the another epitaxial structure having a heterogeneous atoms (such as germanium atoms) in a relative lighter concentration or no heterogeneous atoms at all. Otherwise, the concentration of the heterogeneous atoms (such as germanium atoms) within the first epitaxial layer 152 and the second epitaxial layer 154 may also be altered in a gradual arrangement, but is not limited thereto. Furthermore, it is also noted that there is a spacing T2 in the second direction D2, between the first epitaxial layer 152 and the second epitaxial layer 154, and the spacing T2 is ranged in a proper range. For example, when the critical dimension of the semiconductor device 100 is about 28 nanometer (nm) or less than 28 nm, the spacing T2 is for example ranged between 40 nm and 50 nm, and preferably ranged between 0.045 micrometers (μm) and 0.05 μm. In this way, the first epitaxial layer 152 and the second epitaxial layer 154 may not be too close to each other to generate short circuit or capacitive coupling, and at the same time not to be too far away from each other to loss device integration, but not limited thereto.

It is noteworthy that the aforementioned semiconductor fabricating process of the present embodiment is carried out together with the semiconductor fabricating process performed within the component region 110a, that is, the testkey structure 102 is formed within the testkey region 110b while a semiconductor structure 101 is formed within the component region 110a. In order to synchronously simulate the structural health of an expected testing element, the testkey structure 102 preferably includes the whole layout or at least a partial layout of the expected testing element in the semiconductor structure 101. In the present embodiment, the semiconductor structure 101 also includes a first diffusion region 131, a second diffusion region 133, a plurality of third diffusion regions 135, a plurality of fourth diffusion regions 137, a first gate 141, a second gate 143, a plurality of third gates 145, a plurality of fourth gates 147, a first epitaxial layer 151, and a second epitaxial layer 153. Precisely speaking, the first diffusion region 131, the second diffusion region 133, the third diffusion regions 135, and the fourth diffusion regions 137 are all parallelly extended in the first direction D1, and the first gate 141, the second gate 143, the third gates 145, and the fourth gates 147 are all parallel extended in the second direction D2, so that, the first gate 141 and the second gate 142 may respectively cross the first diffusion region 131 and the second diffusion region 133, also arranged into a rectangular shape R1 as shown in FIG. 1. Furthermore, in the first direction D1, the third diffusion regions 135 and the third gates 145 are all disposed at the first side of the first diffusion region 131, the second diffusion region 133, the first gate 141 and the second gate 143, and each of the third gates 145 crosses over the third diffusion regions 135 or the second diffusion region 133 respectively, and the fourth diffusion regions 137 and the fourth gates 147 are all disposed at the second side of the first diffusion region 131, the second diffusion region 133, the first gate 141 and the second gate 143, and each of the fourth gates 147 crosses over the fourth diffusion regions 137 respectively.

Moreover, the semiconductor structure 101 also includes a first epitaxial layer 151 and a second epitaxial layer 153 disposed on the first diffusion region 131 and the second diffusion region 133, respectively, wherein the materials of the first epitaxial layer 151 and the second epitaxial layer 153 are preferably the same as that of the first epitaxial layer 152 and the second epitaxial layer 154 of the testkey structure 102, for example including SiGe, and also being disposed within the rectangular shape R1. Accordingly, the first diffusion region 131 and the second diffusion region 133, the first gate 141 and the second gate 143, and the first epitaxial layer 151 and the second epitaxial layer 153 may also form at least two PMOS transistors. Also, there is also a spacing T1 in the second direction D2, between the first epitaxial layer 151 and the second epitaxial layer 153, and the spacing T1 includes the same range as that of the spacing T2, for example being about 0.045 μm to 0.05 μm, but is not limited thereto.

In other words, in the present embodiment the semiconductor structure 101 and the testkey structure 102 with the same layout and material are simultaneously formed in the component region 110a and the testkey region 110b through the same semiconductor fabricating process. Following these, each of the gates 140 disposed within the component region 110a and/or the testkey region 110b may be replaced by metal gates via a replacement of metal gate (RMG) process according to practical requirements, or necessary plugs or contact plugs are formed around each of the gates 140, or electrically connected to the testkey structure 102. For example, as shown in FIG. 2, an insulating layer 160 is further disposed on the substrate 110, to serve as an interlayer dielectric layer, to entirely cover on the component region 110a and the testkey region 110b. The insulating layer 160 is filled in the gap between the first epitaxial layer 151 and the second epitaxial layer 153 of the component region 110a, and also filled in the gap between the first epitaxial layer 152 and the second epitaxial layer 154 of the testkey region 110b, so that both of the first epitaxial layer 151 and the second epitaxial layer 153 of the component region 110a, and the first epitaxial layer 152 and the second epitaxial layer 154 of the testkey region 110b, may be isolated from each other, avoiding current in direct connection. Furthermore, a plurality of plugs 171, 172 is formed within the insulating layer 160, to electrically connect to the first epitaxial layer 151, the second epitaxial layer 153 of the component region 110, and the first epitaxial layer 152, the second epitaxial layer 154 of the testkey region 110b, respectively, as shown in FIG. 1.

It is noted that, the plugs 172 which are electrically connected to the first epitaxial layer 152 and the second epitaxial layer 154 of the testkey region 110b may be further electrically connected to an input pad 186 and an output pad 188 respectively, via conductive wires 182, 184 disposed over the plugs 172, wherein the conductive wires 182, 184 are parallelly extended along the first direction D1, without directly in contact with each other. Then, the input pad 186 and the output pad 188 are not directly in contact with each other, as shown in FIG. 1. In the present embodiment, the input pad 186 and the output pad 188 are for example disposed within the testkey region 110b, at the locations where do not overlap with any of the diffusion regions 130, or any of the gates 140, and preferably, the input pad 186 and the output pad 188 are disposed at two opposite sides of the testkey structure 102. Accordingly, each of the diffusion regions 130 (including the first diffusion region 132, the second diffusion region 134, the third diffusion regions 136, and the fourth diffusion regions 138) or each of the gates 140 (including the first gates 142, the second gates 144, the third gates 146, and the fourth gates 148) within the testkey region 110b may be all disposed between the input pad 186 and the output pad 188, without being overlapped with any of the diffusion regions 130 and any of the gates 141 disposed underneath, but not limited thereto.

Through these arrangements, the semiconductor structure 101 disposed within the component region 110a, and the testkey structure 102 which is corresponding to the semiconductor structure 101 of the component region 110a and disposed within the testkey region 110b are both obtained at the same time, with first spacing T1 and the second spacing T2 having the same dimension being respectively disposed between the first epitaxial layer 151 and the second epitaxial layer 153 of the component region 110a, and between the first epitaxial layer 152 and the second epitaxial layer 154 of the testkey region 110b. Thus, the testkey structure 102 in the testkey region 110b may correspondingly simulate and monitor the spacing T1 between the first epitaxial layer 151 and the second epitaxial layer 153 in the component region 110a. In addition, in the present embodiment, the semiconductor structure 101 in the component region 110a may be any semiconductor element for testing the structural health thereof, such as a PMOS transistor, a SPAM, or the like, and preferably for a SPAM, but not limited thereto.

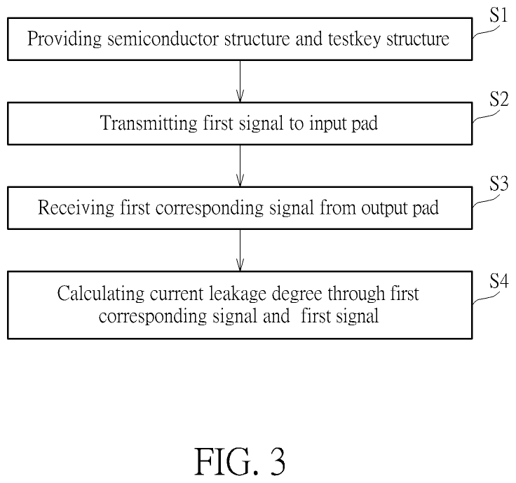

As shown in FIG. 3, FIG. 3 illustrates a schematic flowchart of a monitoring method with a testkey according to one embodiment of the present disclosure. Firstly, the semiconductor structure 101 and the testkey structure 102 as shown in FIG. 1 are provided (STEP S1), and next, a first signal such as a voltage signal is transmitted to the input pad 186 of the testkey structure 102 (STEP S2), and then, a first corresponding signal such as a current signal is received from the output pad 188 of the testkey structure 102 (STEP S3). In this way, the current leakage degree between the first epitaxial layer 152 and the second epitaxial layer 154 of the testkey structure 102 may be calculated through the first corresponding signal and the first signal (STEP S4), and the structural health of the spacing T1 between the first epitaxial layer 151 and the second epitaxial layer 153 of the semiconductor structure 101 may therefore be further evaluated based on the difference between the first corresponding signal and the first signal.

As an example, when a voltage signal is applied to the input pad 186 with the first signal being about 1 volt, the current value or the voltage value received from the output terminal 188 is measured at the same time. If the first corresponding signal received from the output terminal 188 is only in a pico-level or lower than the pico-level, such as 100 pico-amperes (picoamps), that is, the current leakage degree between the first epitaxial layer 152 and the second epitaxial layer 154 of the testkey structure 102 is quite low, or only an induced current caused by capacitive coupling is generated between the first epitaxial layer 152 and the second epitaxial layer 154 of the testkey structure 102. Thus, there is not leakage issues between the first epitaxial layer 152 and the second epitaxial layer 154 of the testkey structure 102, which means that the first epitaxial layer 151 and the second epitaxial layer 153 with the same spacing T1 in the component region 110a have good structural health, and the semiconductor device is adequate to be mass production.

On the other hand, if the first corresponding signal received from the output terminal 188 is in a nano-level or higher than the nano-level, such as nano-amperes, when the first signal is about 1 volt, the current leakage degree between the first epitaxial layer 152 and the second epitaxial layer 154 of the testkey structure 102 is high, referring to leakage issue. The leakage issue may be caused by uneven epitaxial growth rate on the wafer, excessive pattern density of elements, or micro-loading effect while etching the fin-shape structures, which may lead to the small spacing between the adjacent epitaxial structures. In this way, the first epitaxial layer 151 and the second epitaxial layer 153 having the same spacing T1 within the component region 110 do not obtain good structural health, and the semiconductor device is inadequate to be mass production. According to present disclosure, the spacing T1 within the semiconductor structure 101 is fast and precisely monitored with the testkey structure 102, with the spacing between the epitaxial structures (for example the first epitaxial layer 151 and the second epitaxial layer 153) which are adjacent thereto being proper monitored in a non-destructive manner, so that, the fabricating tolerance of the semiconductor process may be effectively evaluated. Thus, the preset disclosure is allowable to avoid the possible current leakage caused by structural defects between the adjacent epitaxial structures, and the yield of products after mass production will be greatly improved.

People well known in the arts should easily realize the testkey structure in the present disclosure is not limited to the aforementioned embodiment, and may further include other layouts. The following description will detail the different embodiments of the testkey structure in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

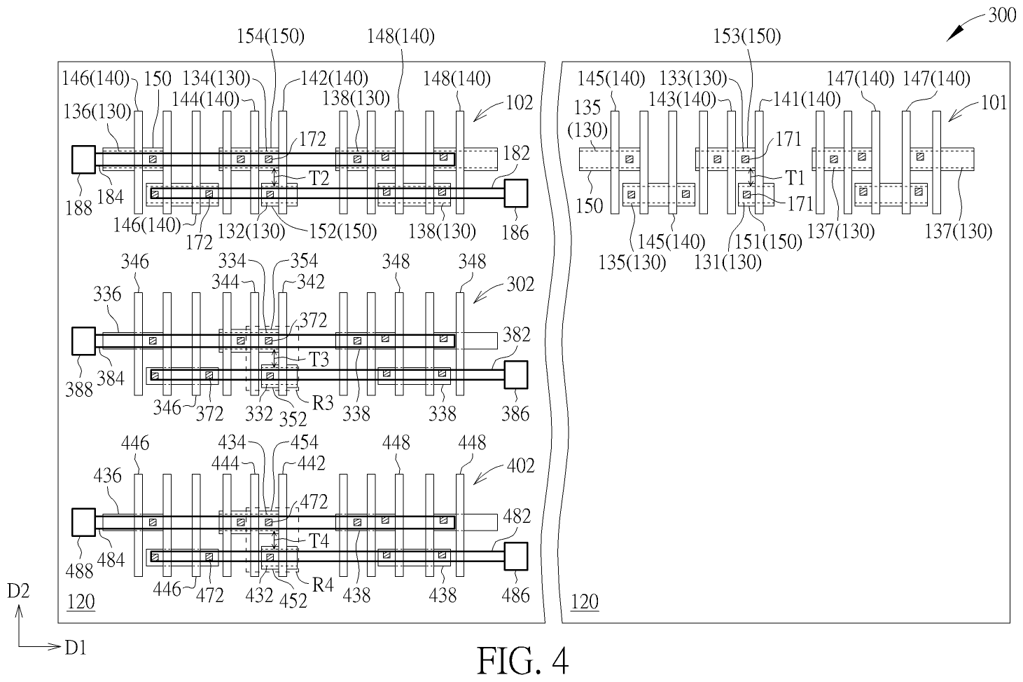

As shown in FIG. 4, FIG. 4 illustrates a schematic top view of a testkey structure according to another embodiment of the present disclosure. Firstly, a semiconductor device 300 is provided, and which also includes the semiconductor structure 101 disposed within the component region 110a, and the testkey structure 102 corresponding to the semiconductor structure 101 and disposed within the testkey region 110b, all similarities will not be redundantly described therein after. The difference between the testkey structure of the present embodiment and the testkey structure of the aforementioned embodiment is mainly in that the semiconductor device 300 includes more than one testkey structure corresponding to the semiconductor structure 101 within the component region 110a, for example including the testkey structure 102, a testkey structure 302, and a testkey structure 402.

Precisely speaking, the testkey structure 302/402 also includes a first diffusion region 332/432, a second diffusion region 334/434, a plurality of third diffusion regions 336/436, a plurality of fourth diffusion regions 338/438, a first gate 342/442, a second gate 344/444, a plurality of third gates 346/446, a plurality of fourth gates 348/448, a first epitaxial layer 352/452, and a second epitaxial layer 354/454. Precisely speaking, the first diffusion region 332/432, the second diffusion region 334/434, the third diffusion regions 336/436, and the fourth diffusion regions 338/438 are all parallelly extended in the first direction D1, and the first gate 342/442, the second gate 344/444, the third gates 346/446, and the fourth gates 348/448 are all parallel extended in the second direction D2, so that, the first gate 342/442 and the second gate 344/444 may respectively cross the first diffusion region 332/432 and the second diffusion region 334/434, also arranging into a rectangular shape R3/R4, as shown in FIG. 4. Furthermore, in the first direction D1, the third diffusion regions 336/436 and the third gates 346/446 are all disposed at the first side of the first diffusion region 332/432, the second diffusion region 334/434, the first gate 342/442 and the second gate 344/444, and each of the third gates 346/446 crosses over the third diffusion regions 336/436 or the second diffusion region 334/434 respectively, and the fourth diffusion regions 338/438 and the fourth gates 348/448 are all disposed at the second side of the first diffusion region 332/432, the second diffusion region 334/434, the first gate 342/442 and the second gate 344/444, and each of the fourth gates 348/448 crosses over the fourth diffusion regions 338/438 respectively.

Moreover, the testkey structure 302/402 also includes a first epitaxial layer 352/452 and a second epitaxial layer 354/454 disposed on the first diffusion region 332/432 and the second diffusion region 334/434, respectively, wherein the materials of the first epitaxial layer 352/452 and the second epitaxial layer 354/454 are preferably the same as that of the first epitaxial layer 152 and the second epitaxial layer 154 of the testkey structure 102, or the first epitaxial layer 151 and the second epitaxial layer 153 of the semiconductor structure 101, for example including SiGe, and also being disposed within the rectangular shape R3/R4. Accordingly, the first diffusion region 332/432 and the second diffusion region 334/434, the first gate 342/442 and the second gate 344/444, and the first epitaxial layer 352/452 and the second epitaxial layer 354/454 may also form at least two PMOS transistors. Also, there is also a spacing T3/T4 in the second direction D2, between the first epitaxial layer 352/452 and the second epitaxial layer 354/454. It is noted that the spacing T3/T4 may include the same range as that of the spacings T1, T2, for example being between 40 nm to 50 nm, and the spacings T2, T3, T4 may respectively include different numbers, for example being 0.043 μm, 0.044 μm, 0.045 μm, 0.046 μm, 0.048 μm, or 0.050 μm. In this way, it is sufficient to establish a database for different fabricating specifications and parameters, or to respectively monitor various corresponding elements with different specifications and sizes on the wafer, for example, with each of the testkey structures being corresponding to a high-voltage element, a medium-voltage element, a low-voltage element or a memory with different spacings in each die, or to respectively monitor the same element with different specifications and sizes in each die. Moreover, the spacing difference between each of the first epitaxial layers and each of the second epitaxial layers in the plurality of the testkey structures may be a fixed value or percentage according to practical product requirements, but not limited thereto.

Then, the first epitaxial layer 352/452 and the second epitaxial layer 354/454 of the testkey structure 302/402 may be further electrically connected to an input pad 386/486 and an output pad 388/488 respectively, via a plurality of plugs 372/472, and conductive wires 382/482, 384/484 disposed over the plugs 372/472, as shown in FIG. 4. Through these arrangements, while using the testkey structures 102, 302, 402 to monitor the spacing, a first signal, a second signal, and a third signal are firstly applied to the input pads 186, 386, 486 of the testkey structures 102, 302, 402 respectively, and a first corresponding signal, a second corresponding signal, and a third corresponding signal are received from the output pads 188, 388, 488 of the testkey structure 102, 302, 402 respectively. In this way, the current leakage degree between the first epitaxial layers 152, 352, 452 and the second epitaxial layers 154, 354, 454 of the testkey structures 102, 302, 402 may be calculated through the first corresponding signal and the first signal, the second corresponding signal and the second signal, and the third corresponding signal and the third signal, so that, the structural health of the spacing T1 between the first epitaxial layer 151 and the second epitaxial layer 153 of the semiconductor structure 101 may be evaluated in a complete and comprehensive manner. In the present embodiment, the practical disposing number of the testkey structures (being three, including the testkey structures 102, 302, 402) is only for example, and which is not limited thereto, and people skilled in the art should fully understand that the disposing number of the testkey structures may be adjustable due to product requirements, to optionally includes a related greater number or a related smaller number of the testkey structures.

In overall speaking, according to the present disclosure, a semiconductor structure is disposed in a component region of a semiconductor device, and at least one testkey structure which is corresponding to the semiconductor structure is simultaneously disposed in a testkey region of the semiconductor device, wherein a first epitaxial layer and a second epitaxial layer are disposed in the component region, with a spacing being defined therebetween, and a corresponding first epitaxial layer and a corresponding second epitaxial layer are disposed in the testkey region with the same spacing being defined therebetween. Through these arrangements, the spacing between the first epitaxial layer and the second epitaxial layer in the component region may be correspondingly simulated and monitored by using the testkey structure in the testkey region, so that, the present disclosure is allowable to effectively monitor the fabricating tolerance of the semiconductor process, thereby effectively avoiding the possible leakage caused by structural defects between adjacent structures, and further increasing the product yield after mass production.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A testkey structure, comprising:
a first diffusion region and a second diffusion region, disposed in a substrate;
a first gate and a second gate, disposed on the substrate, across the first diffusion region and the second diffusion region respectively;
a first epitaxial layer and a second epitaxial layer, disposed on the first diffusion region and the second diffusion region respectively, wherein the first epitaxial layer and the second epitaxial layer are separately disposed between the first gate and the second gate; and
an input pad and an output pad, electrically connected to the first epitaxial layer and the second epitaxial layer respectively.

2. The testkey structure according to claim 1, wherein the first epitaxial layer and the second epitaxial layer comprise silicon germanium.

3. The testkey structure according to claim 1, wherein the first diffusion region, the second diffusion region, the first gate, and the second gate are together arranged in a rectangular shape.

4. The testkey structure according to claim 1, further comprising:
a plurality of third diffusion regions, disposed at a first side of the first diffusion region and the second diffusion region in the substrate;
a plurality of third gates, disposed on the substrate, across the third diffusion regions and the second diffusion region respectively;
a plurality of fourth diffusion regions, disposed at a second side of the first diffusion region and the second diffusion region in the substrate, and the second side being opposite to the first side; and
a plurality of fourth gates, disposed on the substrate, across the fourth diffusion regions respectively.

5. The testkey structure according to claim 4, wherein the first diffusion region, the second diffusion region, the third diffusion regions and the fourth diffusion regions are parallel extended in a first direction, the first gate, the second gate, the third gates and the fourth gates are parallel extended in a second direction, and the first direction is perpendicular to the second direction.

6. The testkey structure according to claim 4, further comprising:
an insulating layer, disposed between the first epitaxial layer and the second epitaxial layer; and
a shallow trench isolation which surrounds the first diffusion region, the second diffusion region, the third diffusion regions and the fourth diffusion regions, wherein the insulating layer is disposed on the shallow trench isolation.

7. The testkey structure according to claim 4, wherein the first gate, the second gate, the third gates and the fourth gates are disposed between the input pad and the output pad.

8. The testkey structure according to claim 1, wherein the first diffusion region and the second diffusion region, the first gate and the second gate, and the first epitaxial layer and the second epitaxial layer comprise at least two P-type metal-oxide semiconductor transistors.

9. A monitoring method with a testkey structure, comprising:
providing a testkey structure in a semiconductor device, the testkey structure comprising:
a first diffusion region and a second diffusion region, disposed in a substrate;
a first gate and a second gate, disposed on the substrate, across the first diffusion region and the second diffusion region respectively;
a first epitaxial layer and a second epitaxial layer, disposed on the first diffusion region and the second diffusion region respectively, wherein the first epitaxial layer and the second epitaxial layer are separately disposed between the first gate and the second gate by a first spacing; and
an input pad and an output pad, electrically connected to the first epitaxial layer and the second epitaxial layer respectively;
transmitting a first signal to the input pad; and
identifying leakage between the first epitaxial layer and the second epitaxial layer through receiving a first corresponding signal from the output pad.

10. The monitoring method with the testkey structure according to claim 9, wherein the first diffusion region, the second diffusion region, the first gate, and the second gate are together arranged into a rectangular shape.

11. The monitoring method with the testkey structure according to claim 9, wherein the testkey structure further comprises:
a plurality of third diffusion regions, disposed in the substrate, at a first side of the first diffusion region and the second diffusion region;
a plurality of third gates, disposed on the substrate, across the third diffusion regions and the second diffusion region respectively;
a plurality of fourth diffusion regions, disposed in the substrate, at a second side of the first diffusion region and the second diffusion region, and the second side being opposite to the first side; and
a plurality of fourth gates, disposed on the substrate, across the fourth diffusion regions respectively.

12. The monitoring method with the testkey structure according to claim 11, wherein the first diffusion region, the second diffusion region, the third diffusion regions and the fourth diffusion regions are parallel extended in a first direction, the first gate, the second gate, the third gates and the fourth gates are parallel extended in a second direction, and the first direction is perpendicular to the second direction.

13. The monitoring method with the testkey structure according to claim 11, wherein the first gate, the second gate, the third gates and the fourth gates are disposed between the input pad and the output pad.

14. The monitoring method with the testkey structure according to claim 11, further compressing:
while forming the first diffusion region and the second diffusion region of the testkey structure in the substrate, forming a first diffusion region and a second diffusion region of a semiconductor structure in a component region of the substrate;
while forming the first gate and the second gate of the testkey structure on the substrate, forming a first gate and a second gate of the semiconductor structure within the component region;
while forming the third diffusion regions and the fourth diffusion regions of the testkey structure in the substrate, forming a plurality of third diffusion regions and a plurality of fourth diffusion regions of the semiconductor structure in the component region of the substrate, at a first side and a second side of the first diffusion region and the second diffusion region of the semiconductor structure respectively;
while forming the third gates and the fourth gates of the testkey structure on the substrate, forming a plurality of third gates and a plurality of fourth gates of the semiconductor structure on the substrate, within the component region, wherein the third gates of the semiconductor structure cross the third diffusion regions or the second diffusion region of the semiconductor structure respectively, and the fourth gates of the semiconductor structure cross the fourth diffusion regions of the semiconductor structure respectively;
while forming the first epitaxial layer and the second epitaxial layer of the testkey structure, forming a first epitaxial layer and a second epitaxial layer of the semiconductor structure within the component region of the substrate, wherein the first epitaxial layer and the second epitaxial layer of the semiconductor structure are separately disposed between the first gate and the second gate of the semiconductor structure by a second spacing, and the second spacing is the same as the first spacing; and
calculating the second spacing through receiving the first corresponding signal from the output pad.

15. The monitoring method with the testkey structure according to claim 11, further comprising:
forming an insulating layer, between the first epitaxial layer and the second epitaxial layer; and
forming a shallow trench isolation to surround the first diffusion region, the second diffusion region, the third diffusion regions and the fourth diffusion regions, wherein the insulating layer is formed on the shallow trench isolation.

16. The monitoring method with the testkey structure according to claim 9, further comprising:
providing another testkey structure in the semiconductor device, the another testkey structure comprising:
another first diffusion region and another second diffusion region, disposed in a substrate;
another first gate and another second gate, disposed on the substrate, across the another first diffusion region and the another second diffusion region of the another testkey structure respectively;
another first epitaxial layer and another second epitaxial layer, disposed on the another first diffusion region and the another second diffusion region of the another testkey structure respectively, wherein the another first epitaxial layer and the another second epitaxial layer of the another testkey structure are separately disposed between the another first gate and the another second gate of the another testkey structure by a third spacing; and
an another input pad and an another output pad, electrically connected to the another first epitaxial layer and the another second epitaxial layer of the another testkey structure respectively.

17. The method of monitoring the spacing within the semiconductor device according to claim 16, wherein the third spacing is different from the first spacing, and the third spacing and the first spacing are ranged from 40 nanometers to 50 nanometers.

18. The method of monitoring the spacing within the semiconductor device according to claim 16, further comprising:
transmitting a second signal to the another input pad; and
identifying leakage between the another first epitaxial layer and the another second epitaxial layer of the another testkey structure through receiving a second corresponding signal from the another output pad.

19. The method of monitoring the spacing within the semiconductor device according to claim 9, wherein the first epitaxial layer and the second epitaxial layer comprise silicon germanium, and the first diffusion region and the second diffusion region, the first gate and the second gate, and the first epitaxial layer and the second epitaxial layer comprise at least two P-type metal-oxide semiconductor transistors.
